(19) United States
(12) Patent Application Publication
(10) Pub. No.: US 2011/0233656 A1
(43) Pub. Date: Sep. 29, 2011

(54) SEMICONDUCTOR DEVICE AND METHOD FOR MANUFACTURING THE SAME

(75) Inventors: Hiroshi OHTA, Hyogo-ken (JP); Yasuto Sumi, Hyogo-ken (JP); Klyoshi Kimura, Hyogo-ken (JP)

(73) Assignee: Kabushiki Kaisha Toshiba, Tokyo (JP)

(21) Appl. No.: 13/049,634

(22) Filed: Mar. 16, 2011

(30) Foreign Application Priority Data
Mar. 24, 2010 (JP) 2010-068876

(51) Int. Cl. H01L 29/78; H01L 21/425

(52) U.S. Cl. 257/329; 438/514; 257/E29.262; 257/E21.473

(57) ABSTRACT

According to one embodiment, a semiconductor device includes a semiconductor layer of a first conductivity type, first semiconductor pillar regions of the first conductivity type and second semiconductor pillar regions of a second conductivity type, a semiconductor region of the first conductivity type, a base region of the second conductivity type, a source region, a first main electrode, a second main electrode and a control electrode. The second semiconductor pillar region includes a plurality of semiconductor regions of the second conductivity type. A difference is provided between peak values of impurity concentration profiles of an uppermost and a lowermost semiconductor regions of the plurality of semiconductor regions, and in the alternately arranging direction of the first and second semiconductor pillar regions, maximum width of the uppermost semiconductor region is generally equal to or narrower than maximum width of the lowermost semiconductor region.

### CROSS-REFERENCE TO RELATED APPLICATIONS

This application is based upon and claims the benefit of priority from the prior Japanese Patent Application No. 2010-68876, filed on Mar. 24, 2010; the entire contents of which are incorporated herein by reference.

### FIELD

Embodiments described herein relate generally to a semiconductor device and a method for manufacturing the same.

### BACKGROUND

The on-resistance of a vertical power MOSFET greatly depends on the electrical resistance of its drift layer serving as a conduction layer. The electrical resistance of the drift layer is determined by its impurity concentration. Thus, the on-resistance can be decreased by increasing the impurity concentration. However, the increase of the impurity concentration results in decreasing the breakdown voltage of the pn junction which the drift layer forms with the base layer. Hence, the impurity concentration cannot be increased above the maximum limit determined by the breakdown voltage. Thus, there is a tradeoff between the device breakdown voltage and the on-resistance.

As an example solution to this problem, the super junction structure is known. In the super junction structure, p-type semiconductor regions and n-type semiconductor regions are laterally and alternately arranged in the drift layer. In the super junction structure, a non-doped layer is artificially produced by equalizing the amount of charge (amount of impurity) contained in the p-type semiconductor region with that contained in the n-type semiconductor region. Thus, while maintaining high breakdown voltage, a current is passed through the highly doped n-type semiconductor region. Hence, low on-resistance beyond the material limit is realized.

A conventional method for manufacturing such a super junction structure is as follows. In an n-type drift layer, p-type buried layers are selectively formed by ion implantation and diffusion. In the next step, another n-type drift layer is stacked thereon, and p-type buried layers are formed by ion implantation and diffusion like the underlying layer. This step is repeated a plurality of times. In another conventional technique, to increase the breakdown voltage of the super junction structure, the impurity concentration is varied between the upper layer and the lower layer in each of the p-type semiconductor regions and the n-type semiconductor regions.

However, if the conventional method is used to form the super junction structure, for instance, then the impurity in the portion of the buried layer having relatively high impurity concentration diffuses into the drift layer in the manufacturing process. This causes a problem of increasing the on-resistance of the drift layer adjacent to this buried layer.

### BRIEF DESCRIPTION OF THE DRAWINGS

FIGS. 1A and 1B are schematic views of the main part of a semiconductor device according to a first embodiment;

FIG. 2 is a schematic plan view of the main part of the semiconductor device according to the first embodiment;

FIGS. 3A and 3B are schematic views of the main part of a semiconductor device according to a variation of the first embodiment;

FIGS. 4A to 6B are schematic sectional views of the main part illustrating a process for manufacturing the semiconductor device according to the first embodiment;

FIGS. 7A and 7B illustrate a method for adjusting the opening width of the resist and the amount of impurity doping;

FIGS. 8A and 8B are schematic views of the main part of a semiconductor device according to a comparative example;

FIG. 9 is a schematic sectional view of the main part illustrating a process for manufacturing the semiconductor device according to the comparative example;

FIGS. 10A and 10B illustrate the operation and effect of the semiconductor device according to the first embodiment;

FIGS. 11A and 11B illustrate the breakdown voltage of the semiconductor device;

FIGS. 12A and 12B are schematic views of the main part of a semiconductor device according to a second embodiment;

FIGS. 13A to 15B are schematic sectional views of the main part illustrating a process for manufacturing the semiconductor device according to the second embodiment; and

FIGS. 16A to 19B are schematic sectional views of the main part illustrating a process for manufacturing the semiconductor device according to a third embodiment.

### DETAILED DESCRIPTION

In general, according to one embodiment, a semiconductor device includes a semiconductor layer of a first conductivity type, first semiconductor pillar regions of the first conductivity type and second semiconductor pillar regions of a second conductivity type, a semiconductor region of the first conductivity type, a base region of the second conductivity type, a source region, a first main electrode, a second main electrode and a control electrode. The first semiconductor pillar regions of the first conductivity type and second semiconductor pillar regions of the second conductivity type are alternately arranged above the semiconductor layer and along a direction parallel to a major surface of the semiconductor layer. The semiconductor region of the first conductivity type is provided above the first semiconductor pillar regions and the second semiconductor pillar regions. The base region of the second conductivity type is provided in the semiconductor region and connected to an upper end of the second semiconductor pillar region. The source region selectively is provided in the base region of the second conductivity type. The first main electrode electrically is connected to the source region. The second main electrode is provided below the semiconductor layer and electrically connected to the semiconductor layer. The control electrode is configured to control electrical continuity between the first main electrode and the second main electrode. The second semiconductor pillar region includes a plurality of semiconductor regions of the second conductivity type which is vertically adjacent and communicating with each other. A difference is provided between peak value of impurity concentration profile of an uppermost semiconductor region of the plurality of semiconductor regions of the second conductivity type and peak value of impurity concentration profile of a lowermost semiconductor region of the plurality of semiconductor regions of the second conductivity type, and in the alternately arranging direction of the first semiconductor pillar regions of the first conductivity type and the second semiconductor pillar regions of the second conductivity type, maximum width of the uppermost semiconductor region is generally equal to or narrower than maximum width of the lowermost semiconductor region.

In general, according to one embodiment, a method is disclosed for manufacturing a semiconductor device. The method can repeat a plurality of times a process configured to form a semiconductor region of a first conductivity type and a process configured to selectively implant second conductivity type impurity into the semiconductor region to form a semiconductor stacked body with a plurality of the semiconductor regions stacked in the semiconductor stacked body. The semiconductor regions are selectively doped with the second conductivity type impurity. The method can diffuse the second conductivity type impurity in each layer of the semiconductor stacked body by heat treatment to form a semiconductor pillar region of the second conductivity type in the semiconductor stacked body. The semiconductor pillar region of the second conductivity type includes a plurality of semiconductor regions containing the second conductivity type impurity. The plurality of semiconductor regions are adjacent and communicating with each other. Each time the semiconductor region is stacked, area of ion implantation region doped with the second conductivity type impurity is varied stepwise, and total amount of the second conductivity type impurity is varied stepwise.

In general, according to one embodiment, a method is disclosed for manufacturing a semiconductor device. The method can repeat a plurality of times a process configured to selectively implant first conductivity type impurity into a surface of a semiconductor layer and a process configured to selectively implant second conductivity type impurity into the surface of the semiconductor layer to form a semiconductor stacked body with a plurality of the semiconductor regions stacked in the semiconductor stacked body. The semiconductor regions each are selectively doped with the first conductivity type impurity and the second conductivity type impurity. The method can diffuse the first conductivity type impurity and the second conductivity type impurity in each layer of the semiconductor stacked body by heat treatment to form a semiconductor pillar region of the first conductivity type and a semiconductor pillar region of the second conductivity type in the semiconductor stacked body. The semiconductor pillar region of the first conductivity type includes a plurality of first semiconductor regions containing the first conductivity type impurity. The plurality of first semiconductor regions are adjacent and communicating with each other, and the semiconductor pillar region of the second conductivity type includes a plurality of second semiconductor regions containing the second conductivity type impurity. The plurality of second semiconductor regions are adjacent and communicating with each other. Each time the semiconductor region is stacked, area of ion implantation region doped with the second conductivity type impurity is varied stepwise, and total amount of the second conductivity type impurity is varied stepwise.

Various embodiments will be described hereinafter with reference to the accompanying drawings.

### First Embodiment

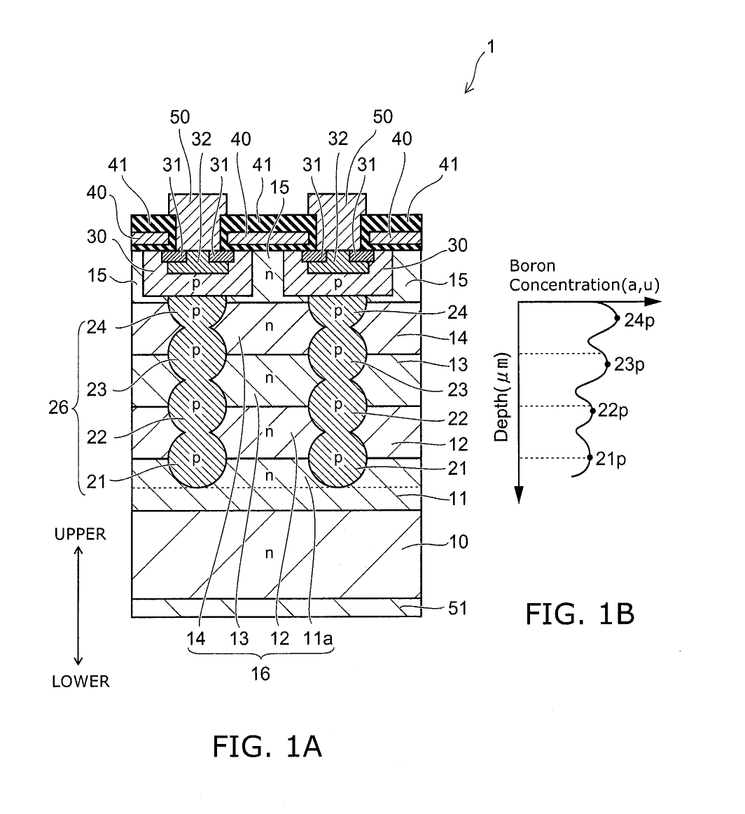

FIGS. 1A and 1B are schematic views of the main part of a semiconductor device according to a first embodiment. Here, FIG. 1A is a schematic sectional view of the main part, and FIG. 1B illustrates a concentration profile.

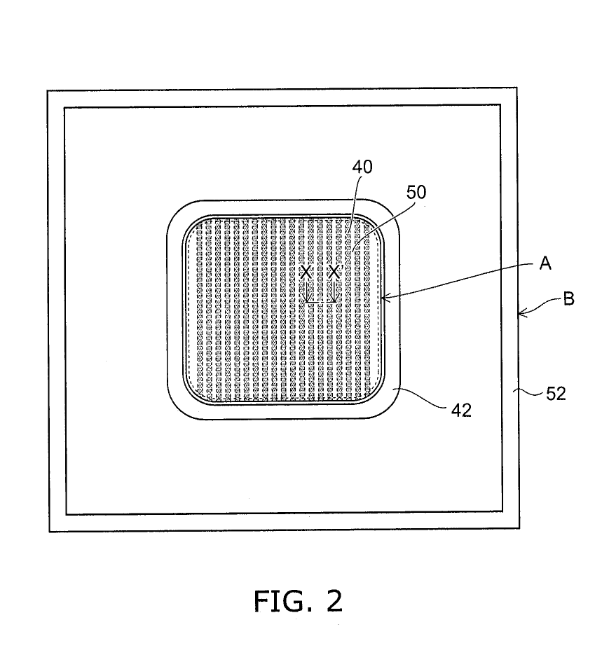

FIG. 2 is a schematic plan view of the main part of the semiconductor device according to the first embodiment.

FIG. 1A shows the X-X′ cross-section of FIG. 2.

The semiconductor device 1 shown in FIGS. 1A and 1B includes a semiconductor layer 10 of the first conductivity type. Above the semiconductor layer 10, the semiconductor device 1 further includes first semiconductor pillar regions 16 of the first conductivity type and second semiconductor pillar regions 26 of the second conductivity type alternately arranged along a direction parallel to the major surface of the semiconductor layer 10. The semiconductor device 1 further includes a semiconductor region 15 of the first conductivity type provided above the semiconductor pillar regions 16 of the first conductivity type and the semiconductor pillar regions 26 of the second conductivity type, a base region 30 of the second conductivity type provided in the semiconductor region 15 and connected to the upper end of the second semiconductor pillar region, and a source region 31 selectively provided in the base region 30. The semiconductor device 1 further includes a source electrode 50 as a first main electrode electrically connected to the source region 31, a drain electrode 50 as a second main electrode provided below the semiconductor layer 10 and electrically connected to the semiconductor layer 10, and a control electrode 40 for controlling electrical continuity between the first main electrode and the second main electrode. Here, the first conductivity type is e.g. n-type, and the second conductivity type is e.g. p-type.

In the semiconductor device 1, on a semiconductor layer (semiconductor substrate) 10 made of n⁺-type silicon (Si), a first-layer n-type semiconductor region 11 is provided. On the semiconductor region 11, a second-layer n-type semiconductor region 12 is provided. On the semiconductor region 12, a third-layer n-type semiconductor region 13 is provided. On the semiconductor region 13, a fourth-layer n-type semiconductor region 14 is provided. On the semiconductor region 14, a fifth-layer n-type semiconductor region 15 is provided. In the semiconductor regions 11-14, a first-layer p-type semiconductor region 21, a second-layer p-type semiconductor region 22 communicating with the semiconductor region 21, a third-layer p-type semiconductor region 23 communicating with the semiconductor region 22, and a fourth-layer p-type semiconductor region 24 communicating with the semiconductor region 23 are provided.

The conductivity type of all the semiconductor regions 11-15 is n-type. The semiconductor regions 11-14 have generally the same impurity concentration (atoms/cm³). The conductivity type of all the semiconductor regions 21-24 is p-type. The semiconductor region 21 is connected to the semiconductor region 22. The semiconductor region 22 is connected to the semiconductor region 23. The semiconductor region 23 is connected to the semiconductor region 24. Here, in the first-layer semiconductor region 11, the region to the depth of the semiconductor region 21 is referred to as semiconductor region 11a.

Thus, n-type semiconductor pillar regions 16 made of the semiconductor regions 11a, 12, 13, 14, and p-type semiconductor pillar regions 26 made of the semiconductor regions 21-24 are repetitively and periodically arranged in a direction generally parallel to the major surface of the semiconductor layer 10. The semiconductor pillar region 26 is made of a plurality of diffusion regions (semiconductor regions 21-24) communicating with each other. The n-type semiconductor pillar region 16 made of the semiconductor regions 11a-14 and the p-type semiconductor pillar region 26 made of the semiconductor regions 21-24 are adjacent to each other to form a pn junction. In other words, the semiconductor device 1 has a super junction structure in which the semiconductor pillar region 16 (semiconductor regions 11a-14) and the semiconductor pillar region 26 (semiconductor regions 21-24) are repetitively joined. The n-type impurity is e.g. phosphorus (P). The p-type impurity is e.g. boron (B).

Furthermore, in the semiconductor device 1, a p-type base region 30 is provided in the semiconductor region 15 above the semiconductor region 24. The lower end of the base region 30 is connected to the upper end of the semiconductor pillar region 26 (upper end of the semiconductor region 24). An n⁺-type source region 31 is selectively provided in the surface of the base region 30. A p⁺-type contact region 32 is selectively provided between the source regions 31 in the surface of the base region 30. The contact region 32 functions as a hole extraction region for extracting holes generated in avalanche breakdown to the source electrode.

An insulating film (gate insulating film) 41 made of e.g. silicon oxide is provided from above the semiconductor region 15 over the base region 30 to halfway above the source region 31. Furthermore, a planar control electrode (gate electrode) 40 is provided in the insulating film 41. Here, instead of the planar structure, the control electrode 40 may have a trench structure.

A source electrode 50 electrically connected to the source region 31 and the contact region 32 is provided on part of the source region 31 and on the contact region 32. A drain electrode 51 electrically connected to the semiconductor layer 10 is provided on the lower side of the semiconductor layer 10.

As viewed from above the semiconductor device 1 (see FIG. 2), the control electrode 40 and the source electrode 50 are each arranged in a striped configuration. The semiconductor pillar regions 16, 26 located below the control electrode 40 and the source electrode 50 are also arranged in a striped configuration along the direction of the control electrode and the source electrode 50. Besides the striped configuration shown in FIG. 2, the super junction structure may be patterned in a concentric configuration.

The MOSFET cell illustrated in FIGS. 1A and 1B is located in a device region indicated by the arrow A. The device region indicated by the arrow A is surrounded by a termination region indicated by the arrow B. A ring-shaped control wiring 42 connected to the control electrode 40 is located on the outer periphery of the device region. An equipotential ring electrode 52 is provided on the outer periphery of the semiconductor device 1.

Furthermore, as shown in FIG. 1B, the impurity concentration peak 22p of the semiconductor region 22 is set generally equal to the impurity concentration peak 21p of the semiconductor region 21. The impurity concentration peak 23p of the semiconductor region 23 is set equal to or higher than the impurity concentration peak 22p of the semiconductor region 22. The impurity concentration peak 24p of the semiconductor region 24 is set equal to or higher than the impurity concentration peak 23p of the semiconductor region 23.

Here, the impurity concentration peak 22p of the semiconductor region 22 may be set higher than the impurity concentration peak 21p of the semiconductor region 21. Such implementation is also encompassed in this embodiment. For instance, the peak value of p-type impurity concentration may be increased stepwise from the semiconductor region 21 toward the semiconductor region 24. Alternatively, in the semiconductor regions 21-24, the peak values of impurity concentration of the vertically adjacent semiconductor regions may be set generally equal.

In the semiconductor regions 21-24 (a plurality of semiconductor regions), the peak values of the impurity concentration profile can be set higher on the source electrode 50 side than on the drain electrode 51 side. That is, the peak value of p-type impurity concentration can be increased stepwise from the semiconductor region 21 toward the semiconductor region 24. In this case, the total amount (number of impurity atoms) of p-type impurity contained in the semiconductor regions 21-24 increases stepwise.

The “width” of each portion is defined as the width in the alternately arranging direction of the semiconductor pillar regions 16, 26. Then, the maximum widths of the semiconductor regions 21-24 are configured to be generally equal. Here, the maximum width of the semiconductor region 21-24 refers to the width of the portion in which the width of the semiconductor region 21-24 is maximized. In the depth direction of the semiconductor device 1, the position of the maximum width of the semiconductor region 21-24 coincides with the position of the corresponding peak 21p-24p. Here, this embodiment also encompasses a configuration in which the maximum width of the semiconductor regions 21-24 is narrowed upward. If the maximum width of the semiconductor regions 21-24 is narrowed upward, then the width of the semiconductor regions 11a-14 is widened upward, and the on-resistance can be reduced.

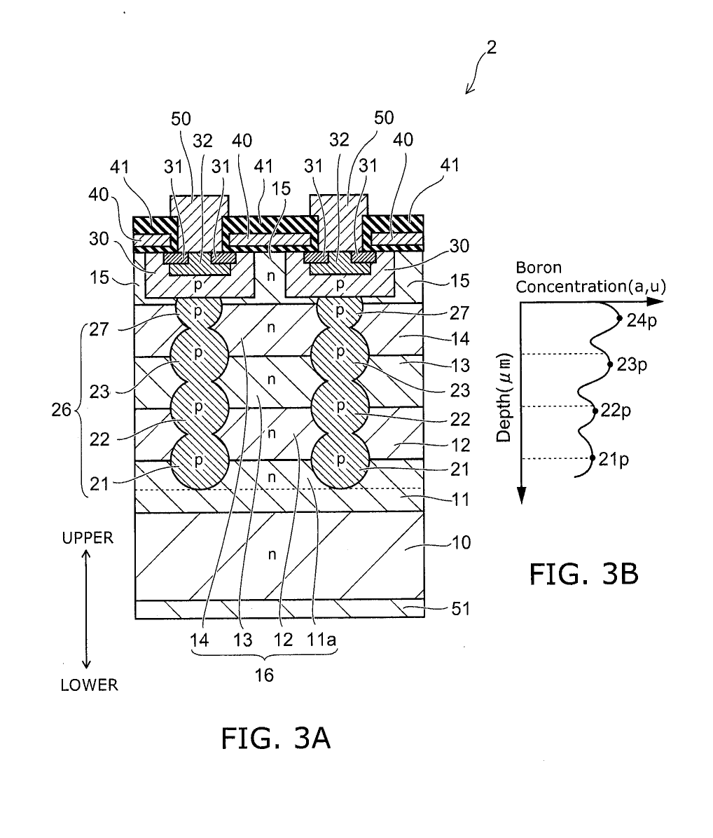

This embodiment also encompasses a configuration in which the maximum width of the uppermost semiconductor region 24 is smaller than the maximum width of the lowermost semiconductor region 21. For instance, FIGS. 3A and 3B are schematic views of the main part of a semiconductor device 2 according to a variation of the first embodiment. Here, FIG. 3A is a schematic sectional view of the main part, and FIG. 3B illustrates a concentration profile. As shown, the maximum width of the uppermost semiconductor region 27 is smaller than the maximum width of the lowermost semiconductor region 21. Such configuration is also encompassed in this embodiment.

Thus, in the semiconductor device 2, a difference is provided between the peak value of the impurity concentration profile of the uppermost semiconductor region 24 and the peak value of the impurity concentration profile of the lowermost semiconductor region 21. The maximum width of the uppermost semiconductor region 24 is equal to or less than the maximum width of the lowermost semiconductor region 21.

Next, a method for manufacturing the semiconductor device 1 is described.

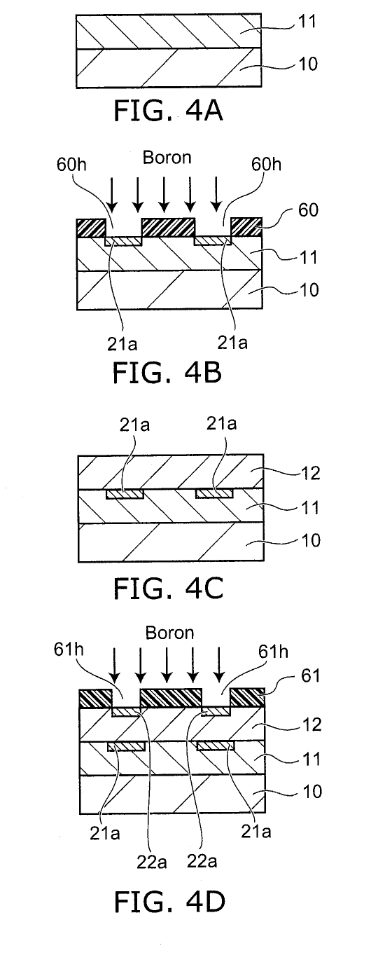

FIGS. 4A to 6B are schematic sectional views of the main part illustrating a process for manufacturing the semiconductor device according to the first embodiment.

As shown in FIG. 4A, a semiconductor region 11 containing n-type impurity such as phosphorus (P) is formed on an n⁺-type semiconductor layer 10. The semiconductor region 11 is formed by e.g. epitaxial growth.

Next, as shown in FIG. 4B, a resist 60 is selectively formed on the surface of the semiconductor region 11. The resist 60 is formed by e.g. photolithography. Subsequently, p-type impurity such as boron (B) is implanted through the opening 60h of the resist 60 into the semiconductor region 11 by ion implantation. Thus, a p-type ion implantation region 21a is selectively formed in the surface of the semiconductor region 11. Then, the resist 60 is removed. The ion implantation region refers to a semiconductor region doped with semiconductor impurity by ion implantation.

Next, as shown in FIG. 4C, a semiconductor region 12 containing n-type impurity such as phosphorus (P) is formed on the semiconductor region 11 and the ion implantation region 21a. The semiconductor region 12 is formed by e.g. epitaxial growth.

Next, as shown in FIG. 4D, a resist 61 is selectively formed on the surface of the semiconductor region 12. The resist 61 is formed by e.g. photolithography. Here, the resist 61 is formed so that the width of the opening 61h of the resist 61 is equal to or less than the width of the opening 60h of the resist 60. For instance, the width of the opening 61h may be generally equal to, or narrower than, the width of the opening 60h. In the example shown in FIG. 4D, the width of the opening 61h is narrower than the width of the opening 60h. Subsequently, p-type impurity such as boron (B) is implanted through the opening 61h of the resist 61 into the semiconductor region 12 by ion implantation. Thus, a p-type ion implantation region 22a is selectively formed in the surface of the semiconductor region 12. The implantation is performed so that the dose amount of the ion implantation region 22a is larger than the dose amount of the ion implantation region 21a. Then, the resist 61 is removed.

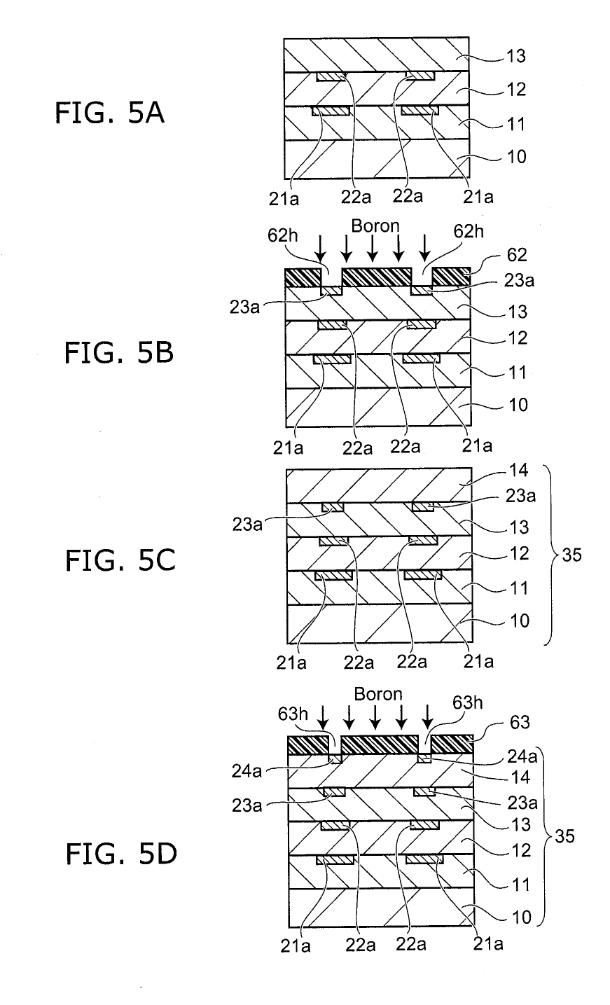

Next, as shown in FIG. 5A, a semiconductor region 13 containing n-type impurity such as phosphorus (P) is formed on the semiconductor region 12 and the ion implantation region 22a. The semiconductor region 13 is formed by e.g. epitaxial growth.

Next, as shown in FIG. 5B, a resist 62 is selectively formed on the surface of the semiconductor region 13. The resist 62 is formed by e.g. photolithography. Here, the resist 62 is formed so that the width of the opening 62h of the resist 62 is equal to or less than the width of the opening 61h of the resist 61. For instance, the width of the opening 62h may be generally equal to, or narrower than, the width of the opening 61h. In the example shown in FIG. 5B, the width of the opening 62h is narrower than the width of the opening 61h. Subsequently, p-type impurity such as boron (B) is implanted through the opening 62h of the resist 62 into the semiconductor region 13 by ion implantation. Thus, a p-type ion implantation region 23a is selectively formed in the surface of the semiconductor region 13. The implantation is performed so that the dose amount of the ion implantation region 23a is larger than the dose amount of the ion implantation region 22a. Then, the resist 62 is removed.

Next, as shown in FIG. 5C, a semiconductor region 14 containing n-type impurity such as phosphorus (P) is formed on the semiconductor region 13 and the ion implantation region 23a. The semiconductor region 14 is formed by e.g. epitaxial growth.

Next, as shown in FIG. 5D, a resist 63 is selectively formed on the surface of the semiconductor region 14. The resist 63 is formed by e.g. photolithography. Here, the resist 63 is formed so that the width of the opening 63h of the resist 63 is equal to or less than the width of the opening 62h of the resist 62. For instance, the width of the opening 63h may be generally equal to, or narrower than, the width of the opening 62h. In the example shown in FIG. 5D, the width of the opening 63h is narrower than the width of the opening 62h. Subsequently, p-type impurity such as boron (B) is implanted through the opening 63h of the resist 63 into the semiconductor region 14 by ion implantation. Thus, a p-type ion implantation region 24a is selectively formed in the surface of the semiconductor region 14. The implantation is performed so that the dose amount of the ion implantation region 24a is larger than the dose amount of the ion implantation region 23a. Then, the resist 63 is removed.

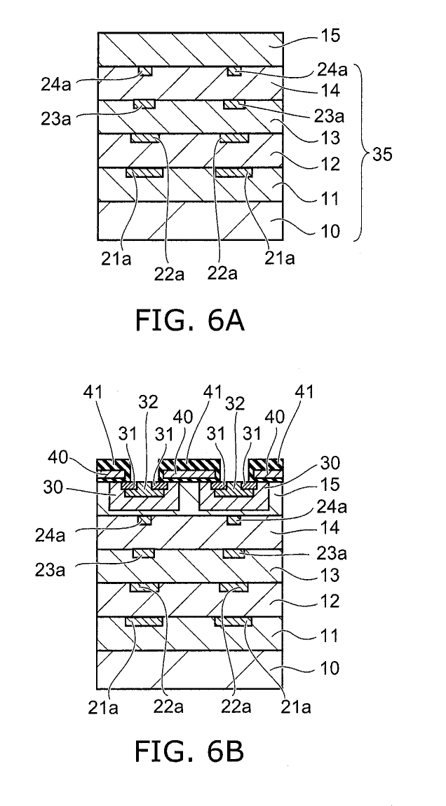

Next, as shown in FIG. 6A, a semiconductor region 15 containing n-type impurity such as phosphorus (P) is formed on the semiconductor region 14 and the ion implantation region 24a. The semiconductor region 15 is formed by e.g. epitaxial growth.

For growth of silicon primarily composing the semiconductor regions 11-15, a raw material gas such as silane (SiH₄), dichlorosilane (SiH₂Cl₂), and trichiorosilane (SiHCl₃) is used. The growth temperature of epitaxial growth is adjusted to e.g. approximately 1000° C. or less.

At this stage, for instance, the width of the ion implantation region 22a is equal to or less than the width of the ion implantation region 21a. The width of the ion implantation region 23a is equal to or less than the width of the ion implantation region 22a. The width of the ion implantation region 24a is equal to or less than the width of the ion implantation region 23a.

The impurity concentration of the ion implantation region 22a is set equal to or more than the impurity concentration of the ion implantation region 21a. The impurity concentration of the ion implantation region 23a is set equal to or more than the impurity concentration of the ion implantation region 22a. The impurity concentration of the ion implantation region 24a is set equal to or more than the impurity concentration of the ion implantation region 23a. For instance, the impurity concentration may be increased stepwise from the ion implantation region 22a toward the ion implantation region 24a.

The total amount of impurity of the ion implantation region 22a is set equal to or more than the total amount of impurity of the ion implantation region 21a. The total amount of impurity of the ion implantation region 23a is set equal to or more than the total amount of impurity of the ion implantation region 22a. The total amount of impurity of the ion implantation region 24a is set equal to or more than the total amount of impurity of the ion implantation region 23a. For instance, the total amount of impurity may be increased stepwise from the ion implantation region 22a toward the ion implantation region 24a.

Thus, the process for forming an n-type semiconductor region and the process for selectively implanting p-type impurity into this semiconductor region are repeated a plurality of times to form a semiconductor stacked body 35. In the semiconductor stacked body 35, a plurality of semiconductor regions with the surface selectively doped with p-type impurity are stacked. Each time a semiconductor region is stacked, the area of the ion implantation region doped with p-type impurity is varied stepwise, and the total amount of p-type impurity is varied stepwise. Specifically, the area of the ion implantation region of p-type impurity is decreased stepwise, and the total amount of p-type impurity is increased stepwise.

Next, the MOSFET formation step is performed on the semiconductor region 15 shown in FIG. 6A. As a result, as shown in FIG. 6B, a base region 30, a source region 31, and a contact region 32 are formed in the surface of the semiconductor region 15. Furthermore, an insulating film 41 and a control electrode 40 are formed. Then, heat treatment is performed on the semiconductor stacked body including the MOSFET.

By this heat treatment, the impurity (boron (B)) of the ion implantation regions 21a, 22a, 23a, 24a diffuses in the respective semiconductor regions 11-15.

Thus, the p-type impurity of the semiconductor regions of the semiconductor stacked body 35 is diffused by heat treatment to form a p-type semiconductor pillar region 26 in the semiconductor stacked body 35. In the semiconductor pillar region 26, a plurality of semiconductor regions (semiconductor regions 21, 22, 23, 24) containing p-type impurity communicate with each other.

Here, the degree of impurity diffusion increases with the increase of impurity concentration of the ion implantation region. Hence, finally, a semiconductor device 1 as shown in FIGS. 1A and 1B is formed. In the semiconductor device 1, the maximum widths of the semiconductor regions 21-24 are generally equal.

The width of the opening of the resist and the amount of impurity doping are adjusted as follows, for instance.

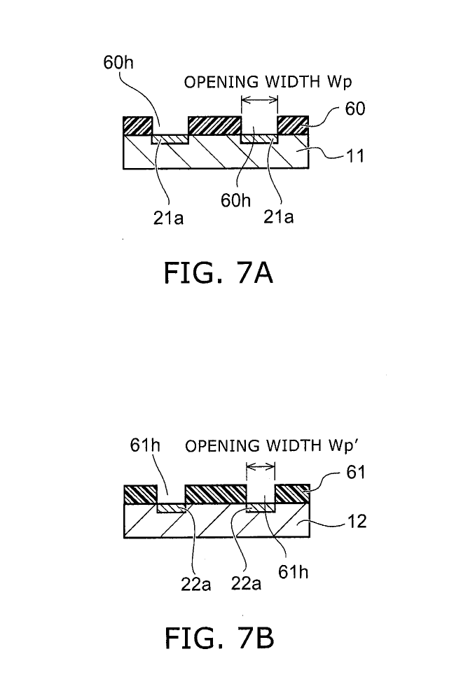

FIGS. 7A and 7B illustrate a method for adjusting the opening width of the resist and the amount of impurity doping.

For instance, the opening width of the opening 60h of the resist 60 illustrated in FIG. 4B is denoted by Wp (see FIG. 7A). The opening width of the opening 61h of the resist 61 is denoted by Wp′. It is assumed that the width of Wp′ is narrower than Wp by 2·ΔW. That is, Wp′=Wp−2·ΔW.

The dose amount implanted into the semiconductor region 11 exposed through the opening 60h of the resist 60 is denoted by Np (/cm²). The dose amount implanted into the semiconductor region 12 exposed through the opening 61h of the resist 61 is denoted by Np′ (/cm²).

The amounts of impurity Qp, Qp′ implanted through the openings 60h, 61h of the resists 60, 61 can be equalized by setting Qp=Qp′ for Qp=Wp×Np, Qp′=Wp′×Np′. This relation can be satisfied by adjustment such that Np′=Wp·Np/(Wp−2·ΔW). Alternatively, the relation Qp<Qp′ can be realized by adjustment such that Np′>Wp·Np/(Wp−2·ΔW).

By such a method, the opening width of the resist and the dose amount at each stage are adjusted.

Next, the operation and effect of the semiconductor device 1 are described.

Before describing the operation and effect of the semiconductor device 1, the operation and effect of a semiconductor device 100 according to a comparative example are described.

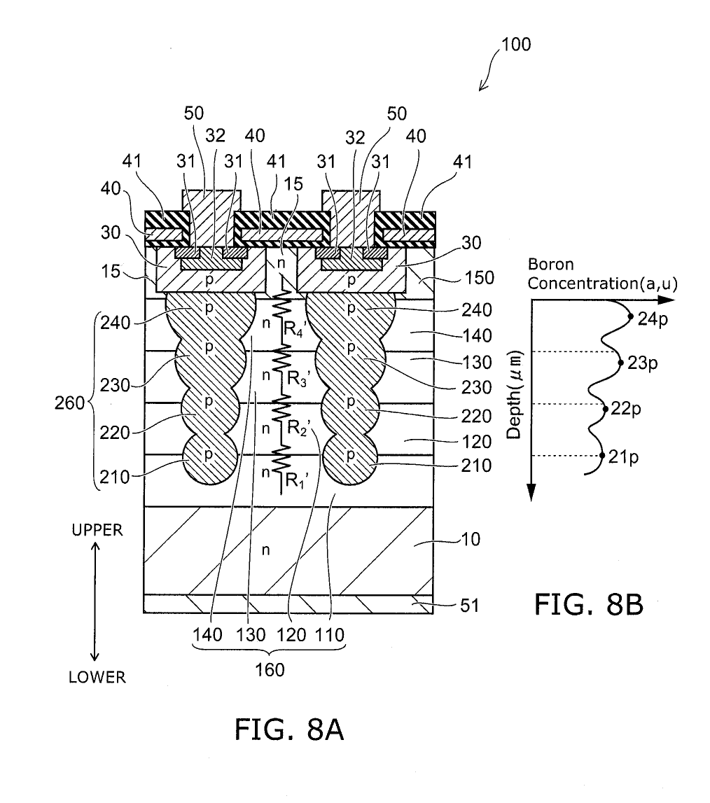

FIGS. 8A and 8B are schematic views of the main part of a semiconductor device according to a comparative example. Here, FIG. 8A is a schematic sectional view of the main part, and FIG. 8B illustrates a concentration profile.

In the semiconductor device 100 according to the comparative example, as shown in FIG. 8B, the impurity concentration peak 220p of the semiconductor region 220 is set higher than the impurity concentration peak 210p of the semiconductor region 210. The impurity concentration peak 230p of the semiconductor region 230 is set higher than the impurity concentration peak 220p of the semiconductor region 220. The impurity concentration peak 240p of the semiconductor region 240 is set higher than the impurity concentration peak 230p of the semiconductor region 230. Thus, the peak value of p-type impurity concentration is increased stepwise from the semiconductor region 210 toward the semiconductor region 240. In this case, the total amount of p-type impurity contained in the semiconductor regions 210-240 increases stepwise.

However, in the semiconductor device 100, the maximum width of the semiconductor regions 210-240 (the width at each peak 210p-240p) is configured as follows. The maximum width of the semiconductor region 220 is wider than the maximum width of the semiconductor region 210. The maximum width of the semiconductor region 230 is wider than the maximum width of the semiconductor region 220. The maximum width of the semiconductor region 240 is wider than the maximum width of the semiconductor region 230.

The reason that the semiconductor device 100 has such a structure is described below.

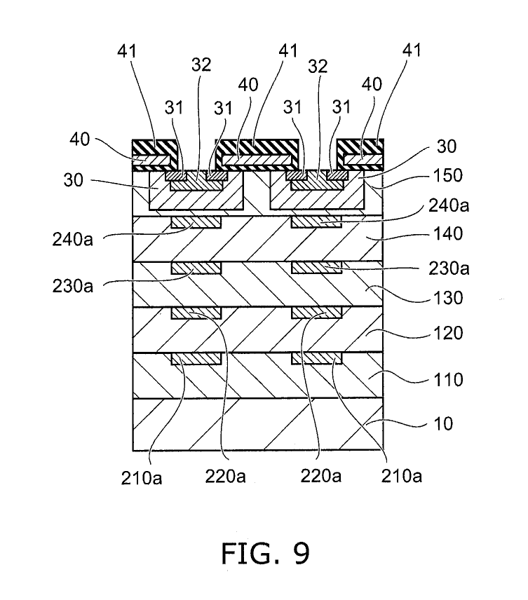

FIG. 9 is a schematic sectional view of the main part illustrating a process for manufacturing the semiconductor device according to the comparative example.

In the process for manufacturing the semiconductor device 100, the openings 60h, 61h, 62h, 63h of the aforementioned resists are all formed with the same opening width. For instance, the manufacturing process is performed so that the opening width of the openings 61h, 62h, 63h is equal to the opening width of the opening 60h, which serves as the reference width. Hence, in the structure of the semiconductor stacked body after formation of the MOSFET, as shown in FIG. 9, the widths of the p-type ion implantation regions 210a, 220a, 230a, 240a are generally equal. Furthermore, the p-type impurity concentration is increased stepwise from the ion implantation region 210a toward the ion implantation region 240a.

In this state, heat treatment is performed on the semiconductor stacked body. Then, the impurity (boron (B)) of the ion implantation regions 210a, 220a, 230a, 240a diffuses in the respective semiconductor regions 110-150. Here, the degree of diffusion increases with the increase of impurity concentration of the ion implantation region. Hence, finally, a semiconductor device 100 as shown in FIGS. 8A and 8B is formed. In the semiconductor device 100, the maximum width of the semiconductor region 220 is wider than the maximum width of the semiconductor region 210. The maximum width of the semiconductor region 230 is wider than the maximum width of the semiconductor region 220. The maximum width of the semiconductor region 240 is wider than the maximum width of the semiconductor region 230.

In this semiconductor device 100, the drain electrode 51 is applied with a higher voltage than the source electrode 50. When the control electrode 40 is applied with a voltage equal to or more than the threshold voltage, a channel is formed in the portion of the base region 30 opposed to the control electrode 40. Thus, a current flows between the source electrode 50 and the drain electrode 51 through the source region 31, the channel, the semiconductor region 150, the semiconductor region 140, the semiconductor region 130, the semiconductor region 120, the semiconductor region 110, and the semiconductor region 10. The semiconductor regions 110-150 are the drift layer of the semiconductor device 100.

However, the maximum width of the semiconductor regions 210-240 widens stepwise from bottom to top. Hence, the width of the semiconductor regions 110-150 sandwiched between the maximum widths of the semiconductor regions 210-240 narrows stepwise. Thus, the electrical resistances R₁′, R₂′, R₃′, R₄′ of the respective portions follow the relation R₁′<R₂′<R₃′<R₄′. That is, the electrical resistance of the drift layer increases toward the base region 30. This unfortunately increases the on-resistance between the source electrode 50 and the drain electrode 51.

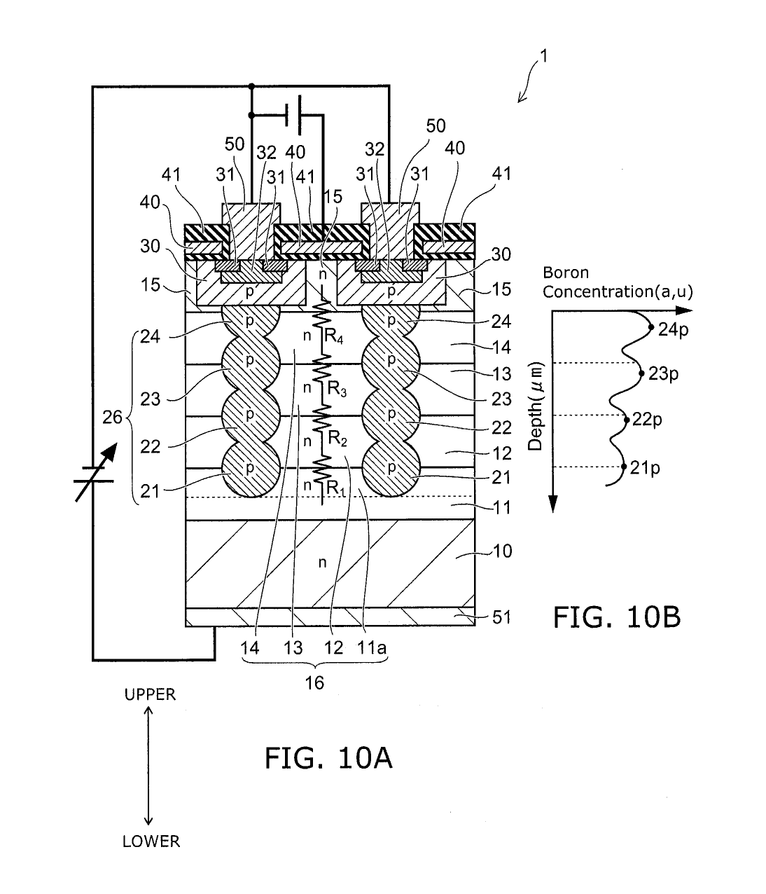

In contrast, FIGS. 10A and 10B illustrate the operation and effect of the semiconductor device according to the first embodiment.

In the semiconductor device 1, the drain electrode 51 is applied with a higher voltage than the source electrode 50. When the control electrode 40 is applied with a voltage equal to or more than the threshold voltage, a channel is formed in the portion of the base region 30 opposed to the control electrode 40. Thus, a current flows between the source electrode 50 and the drain electrode 51 through the source region 31, the channel, the semiconductor region 15, the semiconductor region 14, the semiconductor region 13, the semiconductor region 12, the semiconductor region 11, and the semiconductor region 10. The semiconductor pillar region 16 (semiconductor regions 11a-15) is the drift layer of the semiconductor device 1.

In the semiconductor device 1, the maximum widths of the semiconductor regions 21-24 are configured to be generally equal. Hence, the widths of the semiconductor regions 11a-14 sandwiched between the maximum widths of the semiconductor regions 21-24 are generally equal. The minimum width of the semiconductor regions 12, 13, 14 is wider than that of the semiconductor regions 120, 130, 140. Hence, the electrical resistances of the drift layer follow the relations R₂<R₂′, R₃<R₃′, R₄<R₄′. That is, the on-resistance between the source electrode 50 and the drain electrode 51 is lower in the semiconductor device 1 than in the semiconductor device 100.

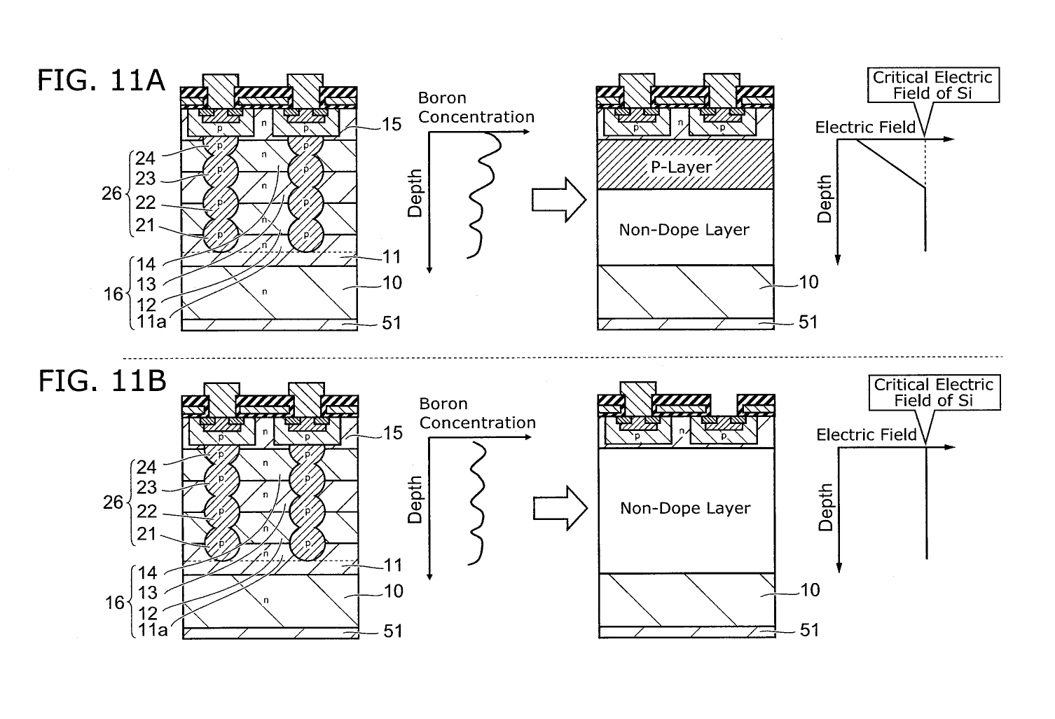

FIGS. 11A and 11B illustrate the breakdown voltage of the semiconductor device.

When the control electrode 40 is applied with a voltage lower than the threshold voltage, the semiconductor device 1 is turned off. Then, the device is applied with high voltage due to the induced electromotive force from e.g. a coil externally connected to the semiconductor device. The problem is the breakdown voltage at this time.

For instance, FIG. 11A shows a configuration in which the impurity concentration of the semiconductor regions 23, 24 is higher than the impurity concentration of the semiconductor regions 13, 14. In this configuration, in an overall view of the semiconductor device 1, the semiconductor regions 23, 24 and the semiconductor regions 13, 14 are apparently doped p-type. Thus, the vertical electric field distribution of the semiconductor region 23 and the semiconductor region 13, and that of the semiconductor region 24 and the semiconductor region 14 have a constant slope. Hence, even in the avalanche state under application of high breakdown voltage, there is room for increasing the electric field, and high avalanche withstand capability can be maintained. That is, the semiconductor device 1 maintains high avalanche withstand capability.

In contrast, FIG. 11B shows a configuration in which the impurity concentration of the semiconductor regions 23, 24 is generally equal to the impurity concentration of the semiconductor regions 13, 14. In this configuration, in an overall view of the semiconductor device 1, the semiconductor regions 23, 24 and the semiconductor regions 13, 14 are apparently non-doped. Thus, the vertical electric field distribution of the semiconductor region 23 and the semiconductor region 13, and that of the semiconductor region 24 and the semiconductor region 14 are constant. Hence, in the avalanche state under application of high breakdown voltage, there is no room for increasing the electric field, and high avalanche withstand capability cannot be maintained.

Furthermore, in the semiconductor device 1, the p-type impurity concentration is sloped from bottom to top of the semiconductor regions 21-24. Hence, even if the concentration of the semiconductor regions 11-15 is varied in the manufacturing process, the balance between the p-type impurity concentration and the n-type impurity concentration is always recovered anywhere at the pn junction interface of the semiconductor pillar region 26 (semiconductor regions 21-24) and the semiconductor pillar region 16 (semiconductor regions 11a-15). That is, in the semiconductor device 1, the tolerance margin is expanded.

Thus, this embodiment realizes a semiconductor device with high avalanche withstand capability and reduced on-resistance.

Next, variations of this embodiment are described. In the following description, like components are labeled with like reference numerals, and the detailed description and manufacturing method thereof are omitted as appropriate.

### Second Embodiment

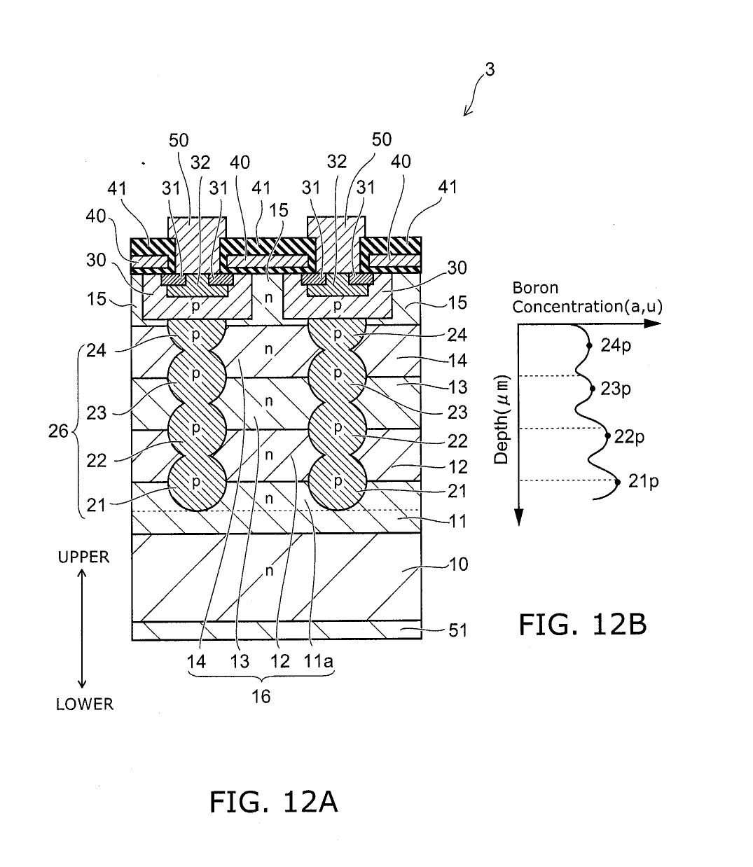

FIGS. 12A and 12B are schematic views of the main part of a semiconductor device according to a second embodiment. Here, FIG. 12A is a schematic sectional view of the main part, and FIG. 12B illustrates a concentration profile.

In the semiconductor device 3, on a semiconductor layer 10, an n-type semiconductor region 11 is provided. On the semiconductor region 11, an n-type semiconductor region 12 is provided. On the semiconductor region 12, an n-type semiconductor region 13 is provided. On the semiconductor region 13, an n-type semiconductor region 14 is provided. On the semiconductor region 14, an n-type semiconductor region 15 is provided. In the semiconductor regions 11-14, a first-layer p-type semiconductor region 21, a second-layer p-type semiconductor region 22 communicating with the semiconductor region 21, a third-layer p-type semiconductor region 23 communicating with the semiconductor region 22, and a fourth-layer p-type semiconductor region 24 communicating with the semiconductor region 23 are provided.

The conductivity type of all the semiconductor regions 11-15 is n-type. The semiconductor regions 11-14 have generally the same impurity concentration. The conductivity type of all the semiconductor regions 21-24 is p-type. The semiconductor region 21 is connected to the semiconductor region 22. The semiconductor region 22 is connected to the semiconductor region 23. The semiconductor region 23 is connected to the semiconductor region 24.

Thus, the semiconductor device 3 has a super junction structure in which the pillar-shaped semiconductor region (semiconductor regions 11-14) and the pillar-shaped semiconductor region (semiconductor regions 21-24) are repetitively joined. The n-type impurity is e.g. phosphorus (P). The p-type impurity is e.g. boron (B).

Furthermore, as shown in FIG. 12B, the impurity concentration peak 22p of the semiconductor region 22 is set equal to or less than the impurity concentration peak 21p of the semiconductor region 21. The impurity concentration peak 23p of the semiconductor region 23 is set equal to or less than the impurity concentration peak 22p of the semiconductor region 22. The impurity concentration peak 24p of the semiconductor region 24 is set equal to or less than the impurity concentration peak 23p of the semiconductor region 23. For instance, the peak value of p-type impurity concentration may be decreased stepwise from the semiconductor region 21 toward the semiconductor region 24. Alternatively, in the semiconductor regions 21-24, the peaks of impurity concentration of the vertically adjacent semiconductor regions may be set generally equal.

In the semiconductor regions 21-24 (a plurality of semiconductor regions), the peak values of the impurity concentration profile can be set lower on the source electrode 50 side than on the drain electrode 51 side. That is, the peak value of p-type impurity concentration can be decreased stepwise from the semiconductor region 21 toward the semiconductor region 24. In this case, the total amount of p-type impurity contained in the semiconductor regions 21-24 decreases stepwise.

The “width” of each portion is defined as the width in the direction parallel to the major surface of the semiconductor layer 10. Then, the maximum widths of the semiconductor regions 21-24 (widths at the respective peaks 21a-24a) in the direction parallel to the major surface of the semiconductor layer 10 are configured to be generally equal. Here, this embodiment also encompasses a configuration in which the maximum width of the semiconductor regions 21-24 is narrowed upward. If the maximum width of the semiconductor regions 21-24 is narrowed upward, then the width of the semiconductor regions 11a-14 is widened upward, and the on-resistance can be reduced.

Next, a method for manufacturing the semiconductor device 3 is described.

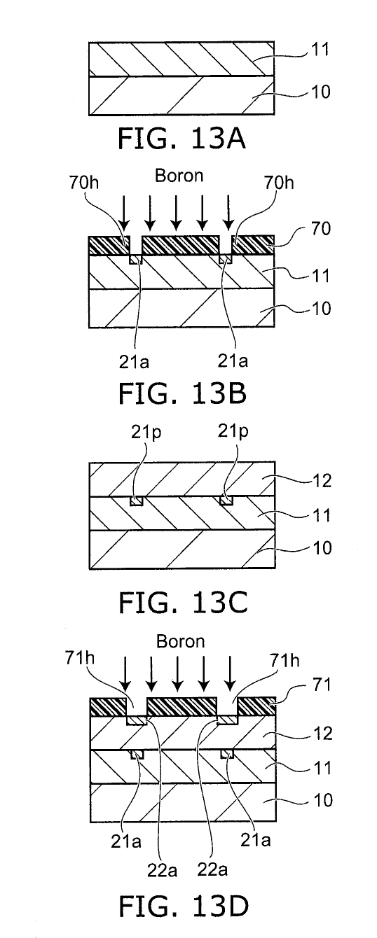

FIGS. 13A to 15B are schematic sectional views of the main part illustrating a process for manufacturing the semiconductor device.

As shown in FIG. 13A, a semiconductor region 11 containing n-type impurity such as phosphorus (P) is formed on an n⁺-type semiconductor layer 10.

Next, as shown in FIG. 13B, a resist 70 is selectively formed on the surface of the semiconductor region 11. Subsequently, p-type impurity such as boron (B) is implanted through the opening 70h of the resist 70 into the semiconductor region 11 by ion implantation. Thus, a p-type ion implantation region 21a is selectively formed in the surface of the semiconductor region 11. Then, the resist 70 is removed.

Next, as shown in FIG. 13C, a semiconductor region 12 containing n-type impurity such as phosphorus (P) is formed on the semiconductor region 11 and the ion implantation region 21a.

Next, as shown in FIG. 13D, a resist 71 is selectively formed on the surface of the semiconductor region 12. The resist 71 is formed so that the width of the opening 71h of the resist 71 is equal to or more than the width of the opening 70h of the resist 70. For instance, the width of the opening 71h may be generally equal to, or wider than, the width of the opening 70h. In the example shown in FIG. 13D, the width of the opening 71h is wider than the width of the opening 70h. Subsequently, p-type impurity such as boron (B) is implanted through the opening 71h of the resist 71 into the semiconductor region 12 by ion implantation. Thus, a p-type ion implantation region 22a is selectively formed in the surface of the semiconductor region 12. The implantation is performed so that the dose amount of the ion implantation region 22a is smaller than the dose amount of the ion implantation region 21a. Then, the resist 71 is removed.

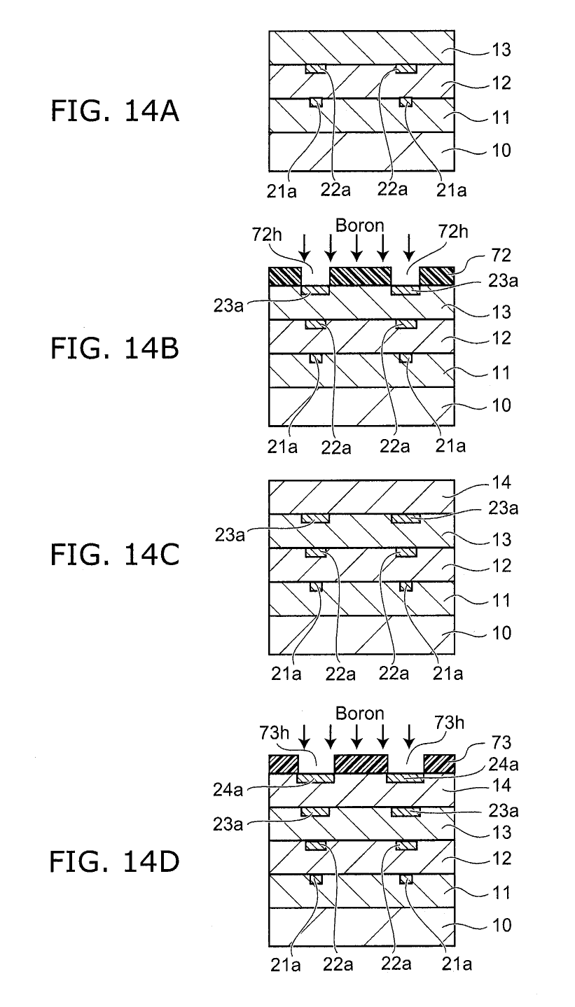

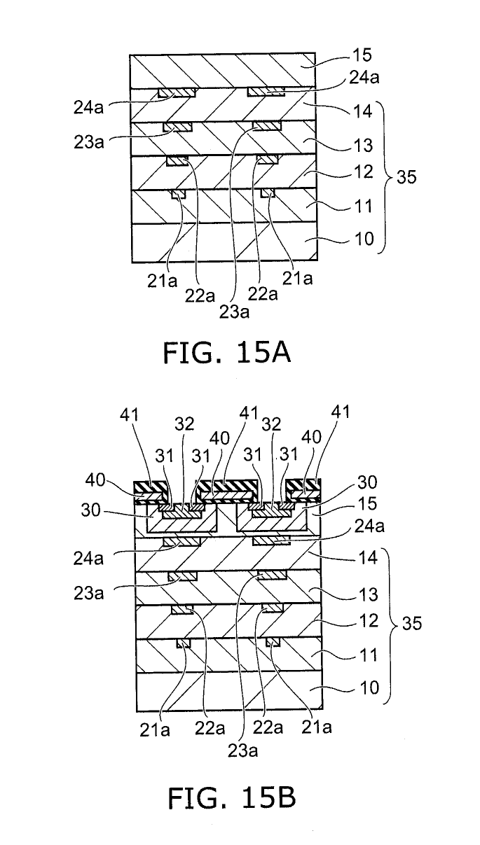

Next, as shown in FIG. 14A, a semiconductor region 13 containing n-type impurity such as phosphorus (P) is formed on the semiconductor region 12 and the ion implantation region 22a.

Next, as shown in FIG. 14B, a resist 72 is selectively formed on the surface of the semiconductor region 13. The resist 72 is formed so that the width of the opening 72h of the resist 72 is equal to or more than the width of the opening 71h of the resist 71. For instance, the width of the opening 72h may be generally equal to, or wider than, the width of the opening 71h. In the example shown in FIG. 14B, the width of the opening 72h is wider than the width of the opening 71h. Subsequently, p-type impurity such as boron (B) is implanted through the opening 72h of the resist 72 into the semiconductor region 13 by ion implantation. Thus, a p-type ion implantation region 23a is selectively formed in the surface of the semiconductor region 13. The implantation is performed so that the dose amount of the ion implantation region 23a is smaller than the dose amount of the ion implantation region 22a. Then, the resist 72 is removed.

Next, as shown in FIG. 14C, a semiconductor region 14 containing n-type impurity such as phosphorus (P) is formed on the semiconductor region 13 and the ion implantation region 23a.

Next, as shown in FIG. 14D, a resist 73 is selectively formed on the surface of the semiconductor region 14. The resist 73 is formed so that the width of the opening 73h of the resist 73 is equal to or more than the width of the opening 72h of the resist 72. For instance, the width of the opening 73h may be generally equal to, or wider than, the width of the opening 72h. In the example shown in FIG. 14D, the width of the opening 73h is wider than the width of the opening 72h. Subsequently, p-type impurity such as boron (B) is implanted through the opening 73h of the resist 73 into the semiconductor region 14 by ion implantation. Thus, a p-type ion implantation region 24a is selectively formed in the surface of the semiconductor region 14. The implantation is performed so that the dose amount of the ion implantation region 24a is smaller than the dose amount of the ion implantation region 23a. Then, the resist 73 is removed.

Next, as shown in FIG. 15A, a semiconductor region 15 containing n-type impurity such as phosphorus (P) is formed on the semiconductor region 14 and the ion implantation region 24a.

At this stage, for instance, the width of the ion implantation region 22a is equal to or more than the width of the ion implantation region 21a. The width of the ion implantation region 23a is equal to or more than the width of the ion implantation region 22a. The width of the ion implantation region 24a is equal to or more than the width of the ion implantation region 23a.

The impurity concentration of the ion implantation region 22a is set equal to or less than the impurity concentration of the ion implantation region 21a. The impurity concentration of the ion implantation region 23a is set equal to or less than the impurity concentration of the ion implantation region 22a. The impurity concentration of the ion implantation region 24a is set equal to or less than the impurity concentration of the ion implantation region 23a. For instance, the impurity concentration may be decreased stepwise from the ion implantation region 22a toward the ion implantation region 24a.

The total amount of impurity of the ion implantation region 22a is set equal to or less than the total amount of impurity of the ion implantation region 21a. The total amount of impurity of the ion implantation region 23a is set equal to or less than the total amount of impurity of the ion implantation region 22a. The total amount of impurity of the ion implantation region 24a is set equal to or less than the total amount of impurity of the ion implantation region 23a. For instance, the total amount of impurity may be decreased stepwise from the ion implantation region 22a toward the ion implantation region 24a.

Thus, the process for forming an n-type semiconductor region and the process for selectively implanting p-type impurity into this semiconductor region are repeated a plurality of times to form a semiconductor stacked body 35. In the semiconductor stacked body 35, a plurality of semiconductor regions with the surface selectively doped with p-type impurity are stacked. Each time a semiconductor region is stacked, the area of the ion implantation region doped with p-type impurity is varied stepwise, and the total amount of p-type impurity is varied stepwise. Specifically, the area of the ion implantation region of p-type impurity is increased stepwise, and the total amount of p-type impurity is decreased stepwise.

Next, the MOSFET formation step is performed on the semiconductor region 15 shown in FIG. 15A. As a result, as shown in FIG. 15B, a base region 30, a source region 31, and a contact region 32 are formed in the surface of the semiconductor region 15. Furthermore, an insulating film 41 and a control electrode 40 are formed. Then, heat treatment is performed on the semiconductor stacked body including the MOSFET.

By this heat treatment, the impurity (boron (B)) of the ion implantation regions 21a, 22a, 23a, 24a diffuses in the respective semiconductor regions 11-15.

Thus, the p-type impurity of the semiconductor regions of the semiconductor stacked body 35 is diffused by heat treatment to form a p-type semiconductor pillar region 26 in the semiconductor stacked body 35. In the semiconductor pillar region 26, a plurality of semiconductor regions (semiconductor regions 21, 22, 23, 24) containing p-type impurity communicate with each other.

Here, the degree of impurity diffusion increases with the increase of impurity concentration of the ion implantation region. Hence, finally, a semiconductor device 3 as shown in FIGS. 12A and 12B is formed. In the semiconductor device 3, the maximum widths of the semiconductor regions 21-24 are generally equal.

In the semiconductor device 3, the maximum widths of the semiconductor regions 21-24 are configured to be generally equal. Hence, the widths of the semiconductor regions 11a-14 sandwiched between the maximum widths of the semiconductor regions 21-24 are generally equal. Thus, as in the semiconductor device 1, the electrical resistances of the drift layer follow the relations R₂<R_{2′, R}₃<R_{3′, R}₄<R₄′. That is, the on-resistance between the source electrode 50 and the drain electrode 51 is lower in the semiconductor device 3 than in the semiconductor device 100.

When the control electrode 40 is applied with a voltage lower than the threshold voltage, the semiconductor device 3 is turned off. Then, the depletion layer extends from the pn junction interface of the base region 30 and the semiconductor regions 14, 15, and the pn junction interface of the semiconductor regions 11-14 and the semiconductor regions 21-24. This allows the semiconductor device 3 to maintain high avalanche withstand capability.

Furthermore, in the semiconductor device 3, the p-type impurity concentration is sloped from bottom to top of the semiconductor regions 21-24. Hence, even if the concentration of the semiconductor regions 11-15 is varied in the manufacturing process, the balance between the p-type impurity concentration and the n-type impurity concentration is always recovered anywhere at the pn junction interface of the semiconductor regions 21-24 and the semiconductor regions 11-15. That is, in the semiconductor device 3, the tolerance margin is expanded.

Thus, this embodiment realizes a semiconductor device with high avalanche withstand capability and reduced on-resistance.

### Third Embodiment

In a third embodiment, the aforementioned semiconductor stacked body is formed by the so-called double implantation.

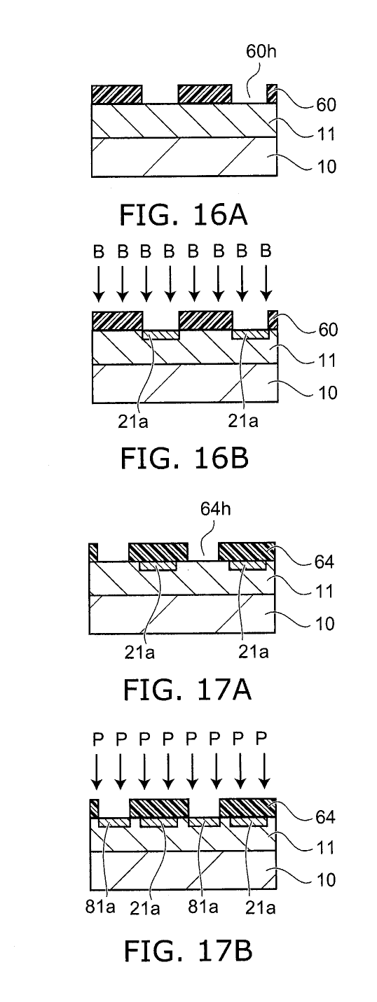

FIGS. 16A to 19B are schematic sectional views of the main part illustrating a process for manufacturing the semiconductor device according to the third embodiment.

As shown in FIG. 16A, a semiconductor region 11 is formed on a semiconductor layer 10. Next, a resist 60 is selectively formed on the surface of the semiconductor region 11.

Next, as shown in FIG. 16B, p-type impurity such as boron (B) is implanted through the opening 60h of the resist 60 into the semiconductor region 11 by ion implantation. Thus, a p-type ion implantation region 21a is selectively formed in the surface of the semiconductor region 11. Then, the resist 60 is removed.

Next, as shown in FIG. 17A, a resist 64 with an opening in the region for forming a semiconductor pillar region 16 is selectively formed on the surface of the semiconductor region 11.

Next, as shown in FIG. 17B, n-type impurity such as phosphorus (P) is implanted through the opening 64h of the resist 64 into the semiconductor region 11 by ion implantation. Thus, an n-type ion implantation region 81a is selectively formed in the surface of the semiconductor region 11. Then, the resist 64 is removed.

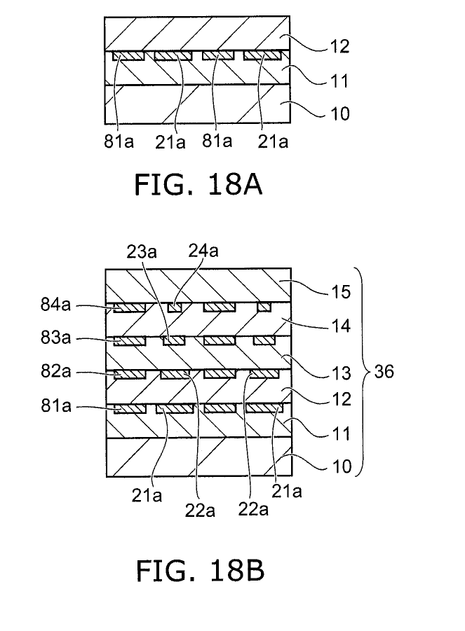

Next, as shown in FIG. 18A, for instance, a semiconductor region 12 is formed on the semiconductor region 11, the ion implantation region 21a, and the ion implantation region 81a.

Then, the manufacturing process as described above is repeated to form a semiconductor stacked body 36 as shown in FIG. 18B. In the semiconductor stacked body 36, the width of the ion implantation region 22a is equal to or less than the width of the ion implantation region 21a. The width of the ion implantation region 23a is equal to or less than the width of the ion implantation region 22a. The width of the ion implantation region 24a is equal to or less than the width of the ion implantation region 23a.

The impurity concentration (dose amount) of the ion implantation region 22a is set equal to or more than the impurity concentration of the ion implantation region 21a. The impurity concentration of the ion implantation region 23a is set equal to or more than the impurity concentration of the ion implantation region 22a. The impurity concentration of the ion implantation region 24a is set equal to or more than the impurity concentration of the ion implantation region 23a. For instance, the impurity concentration may be increased stepwise from the ion implantation region 22a toward the ion implantation region 24a.

The total amount of impurity of the ion implantation region 22a is set equal to or more than the total amount of impurity of the ion implantation region 21a. The total amount of impurity of the ion implantation region 23a is set equal to or more than the total amount of impurity of the ion implantation region 22a. The total amount of impurity of the ion implantation region 24a is set equal to or more than the total amount of impurity of the ion implantation region 23a. For instance, the total amount of impurity may be increased stepwise from the ion implantation region 22a toward the ion implantation region 24a.

The widths and dose amounts of the ion implantation regions 81a-84a are equal.

Thus, the process for selectively implanting p-type and n-type impurity is repeated a plurality of times to form a semiconductor stacked body 36. Each time a semiconductor region is stacked, the area of the ion implantation region doped with p-type impurity is varied stepwise, and the total amount of p-type impurity is varied stepwise. Specifically, the area of the ion implantation region of p-type impurity is decreased stepwise, and the total amount of p-type impurity is increased stepwise.

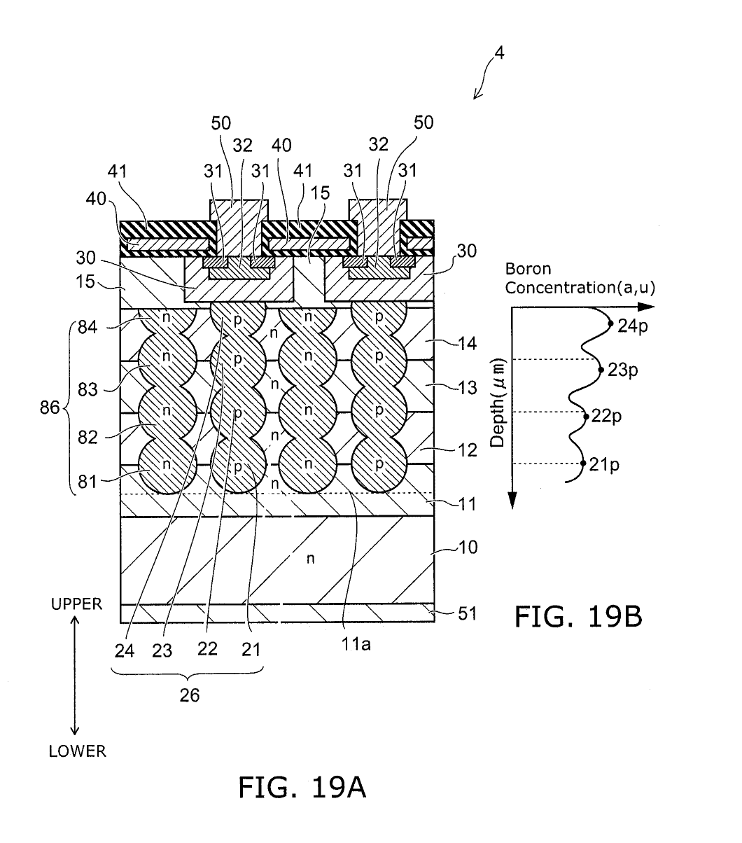

Next, the MOSFET formation step is performed on the semiconductor region 15. As a result, as shown in FIGS. 19A and 19B, a base region 30, a source region 31, and a contact region 32 are formed in the surface of the semiconductor region 15. Furthermore, an insulating film 41 and a control electrode 40 are formed. Then, heat treatment is performed on the semiconductor stacked body 36 including the MOSFET.

By this heat treatment, the impurity of the ion implantation regions 21a-24a, 81a-84a diffuses in the respective semiconductor regions 11-15. Thus, the n-type and p-type impurity of the semiconductor regions of the semiconductor stacked body 36 are diffused by heat treatment. Accordingly, in the semiconductor stacked body 36, a p-type semiconductor pillar region 26 is formed. In the p-type semiconductor pillar region 26, a plurality of semiconductor regions (semiconductor regions 21, 22, 23, 24) containing p-type impurity communicate with each other. Furthermore, an n-type semiconductor pillar region 86 is formed. In the n-type semiconductor pillar region 86, a plurality of semiconductor regions (semiconductor regions 81, 82, 83, 84) containing n-type impurity communicate with each other. Here, the degree of impurity diffusion increases with the increase of impurity concentration of the ion implantation region. Hence, finally, a semiconductor device 4 as shown in FIGS. 19A and 19B is formed. In the semiconductor device 4, the maximum widths of the semiconductor regions 21-24 are generally equal. The method for manufacturing the semiconductor device as described above is also encompassed in this embodiment.

The embodiments of the invention have been described above with reference to examples. However, the invention is not limited to these examples. That is, those skilled in the art can suitably modify these examples, and such modifications are also encompassed within the scope of the invention as long as they fall within the spirit of the invention. For instance, various components of the above examples and their layout, material, condition, shape, size and the like are not limited to those illustrated above, but can be suitably modified.

In the above description of the embodiments, the first conductivity type is n-type, and the second conductivity type is p-type. However, the structure in which the first conductivity type is p-type and the second conductivity type is n-type is also encompassed in the embodiments and achieves a similar effect. Furthermore, the invention can be variously modified and practiced without departing from the spirit thereof.

Furthermore, various components of the above embodiments can be combined with each other as long as technically feasible. Such combinations are also encompassed within the scope of the invention as long as they fall within the spirit of the invention.

Furthermore, those skilled in the art can conceive various modifications and variations within the spirit of the invention. It is understood that such modifications and variations are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a semiconductor layer of a first conductivity type;
first semiconductor pillar regions of the first conductivity type and second semiconductor pillar regions of a second conductivity type alternately arranged above the semiconductor layer and along a direction parallel to a major surface of the semiconductor layer;
a semiconductor region of the first conductivity type provided above the first semiconductor pillar regions and the second semiconductor pillar regions;
a base region of the second conductivity type provided in the semiconductor region and connected to an upper end of the second semiconductor pillar region;
a source region selectively provided in the base region of the second conductivity type;
a first main electrode electrically connected to the source region;
a second main electrode provided below the semiconductor layer and electrically connected to the semiconductor layer; and
a control electrode configured to control electrical continuity between the first main electrode and the second main electrode,
the second semiconductor pillar region including a plurality of semiconductor regions of the second conductivity type being vertically adjacent and communicating with each other,
a difference being provided between peak value of impurity concentration profile of an uppermost semiconductor region of the plurality of semiconductor regions of the second conductivity type and peak value of impurity concentration profile of a lowermost semiconductor region of the plurality of semiconductor regions of the second conductivity type, and
in the alternately arranging direction of the first semiconductor pillar regions of the first conductivity type and the second semiconductor pillar regions of the second conductivity type, maximum width of the uppermost semiconductor region being generally equal to or narrower than maximum width of the lowermost semiconductor region.

2. The device according to claim 1, wherein the maximum widths of the plurality of semiconductor regions of the second conductivity type are generally equal.

3. The device according to claim 1, wherein the peak values of the impurity concentration profile of the plurality of semiconductor regions of the second conductivity type are higher on the first main electrode side than on the second main electrode side.

4. The device according to claim 1, wherein the peak value of impurity concentration of the semiconductor region adjacent to the lowermost semiconductor region is generally equal to the peak value of impurity concentration of the lowermost semiconductor region.

5. The device according to claim 1, wherein the peak values of the impurity concentration profile of the plurality of semiconductor regions of the second conductivity type are generally equal.

6. The device according to claim 1, wherein total amount of impurity of the plurality of semiconductor regions of the second conductivity type are larger on the first main electrode side than on the second main electrode side.

7. The device according to claim 1, wherein positions of the maximum widths of the plurality of semiconductor regions of the second conductivity type coincide with respective positions of the peak values of the impurity concentration profile of the plurality of semiconductor regions of the second conductivity type.

8. The device according to claim 1, wherein the maximum widths of the plurality of semiconductor regions of the second conductivity type are narrower on the first main electrode side than on the second main electrode side.

9. The device according to claim 1, wherein the peak values of the impurity concentration profile of the plurality of semiconductor regions of the second conductivity type are lower on the first main electrode side than on the second main electrode side.

10. The device according to claim 1, wherein total amount of impurity of the plurality of semiconductor regions of the second conductivity type are smaller on the first main electrode side than on the second main electrode side.

11. The device according to claim 1, wherein the first semiconductor pillar region includes a plurality of semiconductor regions of the first conductivity type being vertically adjacent and communicating with each other.

12. The device according to claim 1, wherein the first semiconductor pillar regions and the second semiconductor pillar regions are arranged in a striped configuration as viewed in a direction perpendicular to the major surface of the semiconductor layer.

13. A method for manufacturing a semiconductor device, comprising:
repeating a plurality of times a process configured to form a semiconductor region of a first conductivity type and a process configured to selectively implant second conductivity type impurity into the semiconductor region to form a semiconductor stacked body with a plurality of the semiconductor regions stacked in the semiconductor stacked body, the semiconductor regions being selectively doped with the second conductivity type impurity; and
diffusing the second conductivity type impurity in each layer of the semiconductor stacked body by heat treatment to form a semiconductor pillar region of the second conductivity type in the semiconductor stacked body, the semiconductor pillar region of the second conductivity type including a plurality of semiconductor regions containing the second conductivity type impurity, the plurality of semiconductor regions being adjacent and communicating with each other,
each time the semiconductor region is stacked, area of ion implantation region doped with the second conductivity type impurity being varied stepwise, and total amount of the second conductivity type impurity being varied stepwise.

14. The method according to claim 13, wherein the area of the ion implantation region doped with the second conductivity type impurity is decreased stepwise, and the total amount of the second conductivity type impurity is increased stepwise.

15. The method according to claim 13, wherein the area of the ion implantation region doped with the second conductivity type impurity is increased stepwise, and the total amount of the second conductivity type impurity is decreased stepwise.

16. The method according to claim 13, wherein maximum widths of the semiconductor regions of the semiconductor stacked body are made generally equal.

17. The method according to claim 13, wherein maximum widths of the semiconductor regions of the semiconductor stacked body are narrowed upward.

18. A method for manufacturing a semiconductor device, comprising:
repeating a plurality of times a process configured to selectively implant first conductivity type impurity into a surface of a semiconductor layer and a process configured to selectively implant second conductivity type impurity into the surface of the semiconductor layer to form a semiconductor stacked body with a plurality of the semiconductor regions stacked in the semiconductor stacked body, the semiconductor regions each being selectively doped with the first conductivity type impurity and the second conductivity type impurity; and
diffusing the first conductivity type impurity and the second conductivity type impurity in each layer of the semiconductor stacked body by heat treatment to form a semiconductor pillar region of the first conductivity type and a semiconductor pillar region of the second conductivity type in the semiconductor stacked body, the semiconductor pillar region of the first conductivity type including a plurality of first semiconductor regions containing the first conductivity type impurity, the plurality of first semiconductor regions being adjacent and communicating with each other, and the semiconductor pillar region of the second conductivity type including a plurality of second semiconductor regions containing the second conductivity type impurity, the plurality of second semiconductor regions being adjacent and communicating with each other,
each time the semiconductor region is stacked, area of ion implantation region doped with the second conductivity type impurity being varied stepwise, and total amount of the second conductivity type impurity being varied stepwise.

19. The method according to claim 18, wherein the area of the ion implantation region doped with the second conductivity type impurity is decreased stepwise, and the total amount of the second conductivity type impurity is increased stepwise.

20. The method according to claim 18, wherein the area of the ion implantation region doped with the second conductivity type impurity is increased stepwise, and the total amount of the second conductivity type impurity is decreased stepwise.
